(19) United States
(12) Patent Application Publication
(10) Pub. No.: US 2026/0231702 A1
(43) Pub. Date: Aug. 6, 2026

(54) PASSIVATION ELEMENTS OF A THIN FILM TRANSISTOR

(71) Applicant: ZINITE CORPORATION, Edmonton (CA)

(72) Inventors: Michael CLARK, Edmonton (CA); Douglas W. BARLAGE, Edmonton (CA); Lhing Gem SHOUTE, Edmonton (CA)

(21) Appl. No.: 19/155,171

(22) PCT Filed: Feb. 6, 2024
(86) PCT No.: PCT/IB2024/051078

§ 371 Date: Aug. 8, 2025

Related U.S. Application Data
(60) Provisional application No. 63/444,294, filed on Feb. 9, 2023.

(51) Int. Cl. H10P 14/60; C23C 14/14; C23C 14/34; C23C 16/34; C23C 16/455; C23C 16/50; C23C 28/00; H10D 30/01; H10D 30/67

(52) U.S. Cl. CPC H10P 14/6336; C23C 14/14; C23C 14/34; C23C 16/34; C23C 16/45536; C23C 16/50; C23C 28/32; C23C 28/34; H10D 30/031; H10D 30/6755

(57) ABSTRACT

A novel method of passivizing the surface of elements intended to act as the source and/or drain of a thin film transistor to inhibit the formation of oxides on the surface of those elements during subsequent plasma enhanced deposition process steps is taught. The resulting passivized elements have a layer of plasma enhanced deposition compatible nitride formed on their surface and those structures with that layer of passivation nitride can act as the source and/or drain in a thin film metal oxide transistor, with the plasma enhanced deposition compatible nitride also able to serve as a source channel interfacial member.

### FIELD OF THE INVENTION

The present invention relates to a system and method for the passivation of one or more elements of a transistor. More specifically, the present invention relates to a system and method of passivizing the surface of the source and/or drain in a thin film transistor and a transistor manufactured therewith.

### BACKGROUND OF THE INVENTION

The assignee of the present invention has developed a novel thin film transistor, as described in published PCT applications WO 2023/285936, to Barlage et al. and WO 2023/285951 to Barlage and Shoute and this transistor is referred to herein as a “BTFT”. Amongst other features, BTFTs can be manufactured in Middle of Line (“MOL”) and/or Back End of Line (“BEOL”) semiconductor manufacturing processes and can be formed over conventional MOS transistors.

When manufacturing a BTFT, and other transistors, with a source and/or drain comprising a metal or a material from column IV of the periodic table (i.e.-Silicon, Germanium, tin, etc.) which is subject to oxidation, it is desired to control oxidation of the material to ensure the desired operation of the BTFT.

It is desired to have a convenient and reliable method of passivizing the surface of a source and/or drain in an electronic device.

### SUMMARY OF THE INVENTION

It is an object of the present invention to provide a novel method for passivizing the surface of an element of a thin film transistor which obviates or mitigates at least one disadvantage of the prior art.

According to a first aspect of the present invention, there is provided a method for passivizing the surface of an element serving as one of a source element and a drain element in an electronic device, wherein the element will be subject to plasma enhanced deposition, comprising the steps of: forming the element on a substrate; forming a layer of a plasma enhanced deposition compatible nitride on the surface of the element via plasma enhanced deposition to passivate the surface of the element; and forming a layer of a metal oxide over at least a portion of the passivized surface.

Preferably, the electronic device is a thin film metal oxide transistor and the layer of a plasma enhanced deposition compatible nitride is formed via Atomic layer deposition and serves as a source channel interfacial member between the element and the layer of metal oxide.

According to another aspect of the present invention, there is provided a metal oxide thin film transistor, comprising: a source element formed on a substrate; a layer of plasma enhanced deposition compatible nitride formed over the surface of the source element, the layer of plasma enhanced deposition compatible nitride passivizing the surface of the source element to inhibit the formation of an oxide thereon; a drain element formed on the substrate; a metal oxide semiconductor channel material formed over at least a portion of the source element and the layer of plasma enhanced deposition compatible nitride and contacting the drain element; a gate dielectric formed over the metal oxide semiconductor channel material; and a gate element formed over the gate dielectric.

Preferably, the plasma enhanced deposition process is atomic layer deposition. Also preferably, the thickness of the layer of plasma enhanced deposition compatible nitride is between about 0.8 nm to about 1.2 nm.

Aspects of the present invention provide a novel and useful method of passivizing the surface of metal structures to inhibit the formation of oxides on the surface of those structures during subsequent PEALD or PECVD process steps and a novel thin film metal oxide transistor which employs the passivized elements.

### BRIEF DESCRIPTION OF THE DRAWINGS

Preferred embodiments of the present invention will now be described, by way of example only, with reference to the attached Figures, wherein:

FIG. 1 shows a plot of the measured thickness of a molybdenum member with a metal oxide layer formed on it using a prior art process;

FIG. 2 shows a plot of the thickness of a molybdenum member with a metal oxide layer formed on it using a process in accordance with an aspect of the present invention; and

FIG. 3 shows a cross section of a thin film transistor employing a passivated source in accordance with an aspect of the present invention.

### DETAILED DESCRIPTION OF THE INVENTION

When constructing a BTFT, or a conventional TFT, one of the decisions made is to select the material for the transistor's source and drain elements. In many cases, these elements will be selected to be a material such as a metal or a member of column IV of the periodic table which, ideally, acts as a good source of electrons. Examples of such materials include metals such as, without limitation: molybdenum; tungsten; nickel; ruthenium; cobalt; and alloys thereof; and other materials such as column IV materials including, without limitation, silicon, germanium, and alloys thereof.

BTFTs, and other TFTs, can be formed by sputtering the source and/or drain elements onto a substrate and then forming the semiconductor channel material between them via a plasma enhanced deposition process, such as plasma enhanced atomic layer deposition (PEALD) or plasma enhanced chemical vapor depositon (PECVD), and then forming the gate over the semiconductor channel material.

However the manufacturing processes used to complete manufacture of the TFTs, in particular the oxygen plasma forming steps of Plasma Enhanced deposition processes, results in the oxidation of the surface of the source and/or drain, elements forming an insulating oxide layer thereon and resulting in a non-functional TFT.

The present inventors have determined that by first forming a layer of a PEALD or PECVD compatible nitride on the source and/or the drain elements, subsequent undesired oxidization of the surface of these elements can be inhibited. Examples of suitable PEALD and PECVD nitrides include, without limitation: silicon nitride (Si₃N4), tin nitride (SnNₓ), titanium nitride (TiN), aluminum nitride (AlN), germanium nitride (Ge₃N4), hafnium nitride (HfN), zirconium nitride (ZrN), etc.

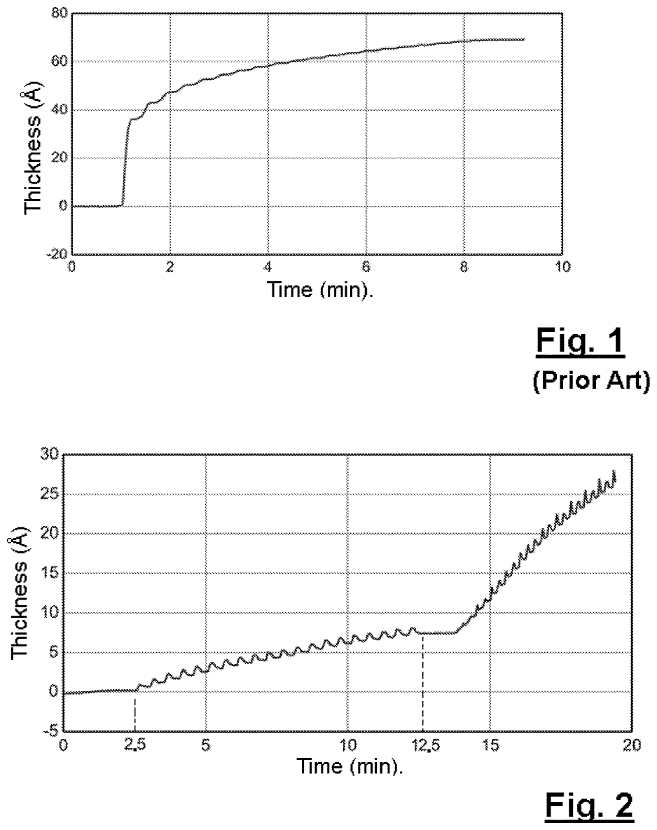

An example of the present invention is now given wherein molybdenum has been selected to act as the source element in a BTFT and the plasma enhanced deposition process is PEALD. FIG. 1 shows a plot of the thickness of the molybdenum source element as a semiconductor layer is formed over it with conventional PEALD processes in accordance with known methods.

In the Figure, the molybdenum source element has been formed on a substrate via sputtering and the substrate carrying the molybdenum source element has been transferred to an ALD device in vacuum to prevent oxidation.

At time t=1 minute in the Figure, a first layer of the organometallic precursor for making a metal oxide semiconductor channel, in this example Tin Oxide (SnO₂) has been formed over the molybdenum to obtain the reference thickness, shown in the Figure as 0 angstroms.

At time t>1 minute, the organometallic layer on the molybdenum is treated with oxygen plasma to remove the carbon groups. As can be seen, a significant increase in the measured thickness of the molybdenum and metal oxide semiconductor structure occurs-a initial increase of approximately 38 angstroms (Å).

As subsequent layers of the metal oxide semiconductor are formed by the following cycles of PEALD (e.g.—from times t=1 to t=6) the increase in thickness initially experienced from the first oxygen plasma treatment at t>1 minute is much, much larger than the increase in thickness as additional layers of metal oxide channel material are formed via PEALD.

The present inventors have determined that this initial large jump in thickness is a result of the oxidation of the surface of molybdenum due to the oxygen plasma treatment and that oxidation prevents the desired operation of the molybdenum (or other source element or drain element material) in the BTFTs.

Accordingly, in accordance with an aspect of the present invention, it has been determined that passivation of the surface of the molybdenum, or other selected source element or drain element material, with a suitable PEALD or PECVD nitride, such as Silicon Nitride (Si₃N₄) or other suitable nitride, examples of which are listed above, inhibits the formation of oxide on the surface of the source and/or drain element material, thus enabling subsequent PEALD or PECVD process steps to form the desired semiconductor metal oxide while inhibiting oxidation of the source element and/or drain element and providing the desired operation of the BTFT or TFT.

FIG. 2 shows the measured thickness of a molybdenum source element, as first a layer of Si₃N₄ is formed on the source element, followed by the formation of the desired semiconductor metal oxide for the channel of a TFT using PEALD processes in accordance with an aspect of the present invention.

In FIG. 2, the thickness of the molybdenum source element, formed for example by sputtering and having been moved to the ALD tool in vacuum to prevent oxidation, is the reference point at t=0 and thickness=0.

From time t=2.5 to time t=12.5, PEALD cycles are commenced to form a layer of Si₃N₄ on the surface of the molybdenum. As can been seen, each PEALD cycle adds approximately one-half of an angstrom to the layer of Si₃N₄ formed on the molybdenum. These regular, small, increases in the overall thickness of the molybdenum source element and the layer of Si₃N₄ make it clear that little or no oxidation has occurred on the molybdenum source element.

At time t=14, formation of the metal oxide semiconductor layer commences. As can again be clearly seen from the Figure, the regular, small, increases in the overall thickness of the molybdenum source element and its over-layers show that little or no oxidation of the molybdenum source element has occurred.

Further, subsequent tests of BTFTs formed by the process of FIG. 2 show that the desired electrical operation of the BTFTs was achieved as substantially no oxidation of the molybdenum source element occurred. Similar results are obtained with the other example source materials listed above and with the other nitride compounds listed above.

As is known from the above-mentioned Barlage published patent applications, BTFTs employ a source-channel interfacial member to achieve their desired performance. A further advantage of the present invention is that, in some circumstances, the passivizing layer applied to the source metal to prevent oxidation of the source can also serve as the source-channel interfacial member.

For example, it has been determined that when passivizing a molybdenum source element with a layer of Si₃N₄, having a thickness of about 1 nm, results in the Si₃N₄ acting as a very effective source-channel interfacial member in the resulting BTFT.

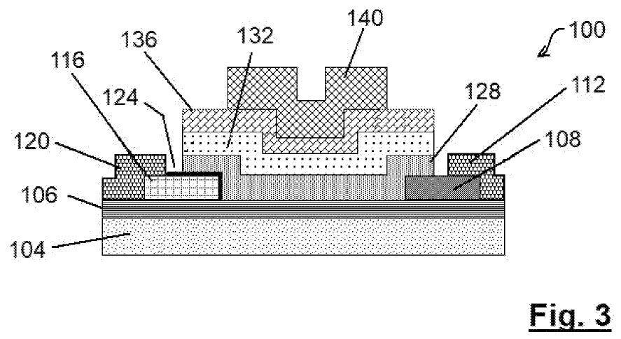

FIG. 3 shows a cross section of an example of a BTFT 100 in accordance with an aspect of the present invention. BTFT 100 is formed on a substrate 104, which can be any suitable substrate, such as a silicon wafer, glass, a polymer, etc., upon which an insulating layer 106 (such as silicon dioxide, etc.) has been formed. BTFT 100 further includes a drain 108 and a drain contact 112, and a source 116 and source contact 120. As can be seen, source 120 has been passivated with a plasma enhanced deposition compatible nitride layer 124, which in this example, also serves as a source-channel interfacial member. BTFT 100 further includes a metal oxide semiconductor layer 128, such as tin oxide, and over which a gate dielectric 132, a gate 136 and a gate contact 140 are formed.

The present invention provides a novel and useful method of passivizing the surface of a source element and/or drain element of a BTFT and/or TFT to inhibit the formation of oxides on the surface of the source element and/or drain element during subsequent PEALD or PECVD process steps. Further, when the source element is to serve as the source in a Barlage-type TFT, the passivating nitride layer can serve as the source-channel interfacial member. In such a case, the passivating nitride layer is formed on the source member with a thickness of about 1 nm, or from about 0.8 nm to about 1.2 nm.

The above-described embodiments of the invention are intended to be examples of the present invention and alterations and modifications may be effected thereto, by those of skill in the art, without departing from the scope of the invention which is defined solely by the claims appended hereto.

We claim:

1. A method for passivizing the surface of an element serving as one of a source element and a drain element in an electronic device, wherein the element will be subject to plasma enhanced deposition, comprising the steps of:
forming the element on a substrate;
forming a layer of a plasma enhanced deposition compatible nitride on the surface of the element via plasma enhanced deposition to passivate the surface of the element; and
forming a layer of a metal oxide over at least a portion of the passivized surface.

2. The method of claim 1 wherein the element is formed by sputtering.

3. The method of claim 1 wherein the element is a metal selected from the group comprising: molybdenum; tungsten; nickel; ruthenium; cobalt; and alloys thereof.

4. The method of claim 1 wherein the element is a selected from column IV of the periodic table.

5. The method of claim 1 wherein the plasma enhanced deposition compatible nitride is selected from the group comprising: silicon nitride (Si₃N₄); tin nitride; (TiN); aluminum nitride (AlN); germanium nitride (Ge₃N₄); hafnium nitride (HfN); and zirconium nitride (ZrN).

6. The method of claim 1 wherein the electronic device is a thin film transistor.

7. The method of claim 6 wherein the element is a source element and the metal oxide layer is intended to form a semiconductor channel.

8. The method of claim 7 wherein the layer of plasma enhanced deposition compatible nitride forms a source-channel interfacial member between the source and the metal oxide layer.

9. The method of claim 8 wherein the thickness of the layer of plasma enhanced deposition compatible nitride is from about 0.8 nm to about 1.2 nm.

10. The method of claim 8 wherein the thickness of the layer of plasma enhanced deposition compatible nitride is about 1.0 nm.

11. The method of claim 1 wherein the electronic device is a thermionic device.

12. The method of claim 1 wherein the plasma enhanced deposition is plasma enhanced atomic layer deposition.

13. The method of claim 1 wherein the plasma enhanced deposition is plasma enhanced chemical vapor deposition.

14. A metal oxide thin film transistor, comprising:
a source element formed on a substrate;
a layer of plasma enhanced deposition compatible nitride formed over the surface of the source element, the layer of plasma enhanced deposition compatible nitride passivizing the surface of the source element to inhibit the formation of an oxide thereon;
a drain element formed on the substrate;
a metal oxide semiconductor channel material formed over at least a portion of the source element and the layer of plasma enhanced deposition compatible nitride and contacting the drain element;
a gate dielectric formed over the metal oxide semiconductor channel material; and
a gate element formed over the gate dielectric.

15. The metal oxide thin film transistor of claim 14 wherein the layer of plasma enhanced deposition compatible nitride acts as a source-channel interfacial member between the source element and the metal oxide semiconductor channel material.

16. The metal oxide thin film transistor of claim 15 wherein the thickness of the layer of plasma enhanced deposition compatible nitride is between about 0.8 nm to about 1.2nm.

17. The metal oxide thin film transistor of claim 15 wherein the thickness of the layer of plasma enhanced deposition compatible nitride is about 1.0 nm.
